(19) United States
(12) Patent Application Publication
(10) Pub. No.: US 2026/0013120 A1
(43) Pub. Date: Jan. 8, 2026

(54) READ-ONLY MEMORY ARRAY AND READ-ONLY MEMORY THEREOF

(71) Applicant: YIELD MICROELECTRONICS CORP., ZHUBEI CITY (TW)

(72) Inventors: YU-TING HUANG, ZHUBEI CITY (TW); CHI-PEI WU, ZHUBEI CITY (TW)

(21) Appl. No.: 18/817,353

(22) Filed: Aug. 28, 2024

(30) Foreign Application Priority Data
Jul. 3, 2024 (TW) 113124946

(51) Int. Cl. H10B 20/25

(52) U.S. Cl. CPC H10B 20/25

(57) ABSTRACT

The disclosure describes a read-only memory array and a read-only memory thereof. The read-only memory array includes common-source lines, word bit lines perpendicular to the common-source lines, and sub-memory arrays. The common-source lines include a first common-source line and a second common-source line. The word bit lines include a first word bit line and a second word bit line. Each sub-memory array includes four memory cells. Each memory cell has a control terminal coupled to the corresponding word bit line and a data terminal coupled to the corresponding common-source line and the corresponding word bit line. The read-only memory includes a field-effect transistor and a capacitor formed in a semiconductor region. The field-effect transistor and the capacitor commonly include a doped well. The doped well, overlapping the common-source line, is coupled to the common-source line.

### BACKGROUND OF THE INVENTION

This application claims priority for the TW patent application No. 113124946 filed on 3 Jul. 2024, the content of which is incorporated by reference in its entirely.

### FIELD OF THE INVENTION

The present invention relates to a memory device, particularly to a read-only memory array and a read-only memory thereof.

### DESCRIPTION OF THE RELATED ART

The Complementary Metal Oxide Semiconductor (CMOS) technology has been developed as a commonly used process for fabricating Application Specific Integrated Circuits (ASIC). Nowadays, as the computer information products are blooming, flash memories and Electrically Erasable Programmable Read Only Memory (EEPROM) have been widely used in electronic products since the data stored within will not volatilize but can be erased and programmed electrically. In addition, the data will not disappear even after the power is turned off.

Non-volatile memories are programmable and are able to adjust gate voltages of their transistors by storing charges, or to preserve the original gate voltages of transistors by not storing charges. When regarding to erase a non-volatile memory, the charges stored in the non-volatile memory are removed to resume the initial state of the memory, and return to its original gate voltages of the transistors. When the non-volatile memory is programmed, its internal switches will be turned off or turned on. In order to program the non-volatile memory array, a certain voltage and current need to be applied, so that the corresponding switches can be turned on or off. However, the existing read-only memories use heavily-doped areas as sources and drains, which cannot withstand high voltages, resulting in low reliability, life, performance, and anti-interference capabilities of the memories.

To overcome the abovementioned problems, the present invention provides a read-only memory array and a read-only memory thereof, so as to solve the afore-mentioned problems of the prior art.

### SUMMARY OF THE INVENTION

The present invention provides a read-only memory array and a read-only memory thereof, which withstand high voltages to improve reliability, life, performance, and anti-interference capabilities.

In an embodiment of the present invention, a read-only memory array is provided. The read-only memory array includes a plurality of common-source lines, a plurality of word bit lines, and a plurality of sub-memory arrays. The common-source lines, arranged in parallel, include a first common-source line and a second common-source line. The word bit lines are arranged in parallel. The word bit lines perpendicular to the common-source lines include a first word bit line and a second word bit line. Each sub-memory array is coupled to two common-source lines and two word bit lines. Each sub-memory array includes a first memory cell, a second memory cell, a third memory cell, and a fourth memory cell. The control terminal of the first memory cell is coupled to the first word bit line. The data terminal of the first memory cell is coupled to the first common-source line and the first word bit line. The control terminal of the second memory cell is coupled to the second word bit line and the data terminal of the second memory cell is coupled to the first common-source line and the second word bit line. The control terminal of the third memory cell is coupled to the second word bit line and the data terminal of the third memory cell is coupled to the second common-source line and the second word bit line. The control terminal of the fourth memory cell is coupled to the first word bit line and the data terminal of the fourth memory cell is coupled to the second common-source line and the first word bit line. The first memory cell, the second memory cell, the third memory cell, and the fourth memory cell, formed in a semiconductor region having a first conductivity type, commonly include a first doped well and a second doped well having a second conductivity type opposite to the first conductivity type. The first doped well and the second doped well are formed in the semiconductor region. The first doped well overlaps the first common-source line. The first doped well is coupled to the first common-source line. The second doped well overlaps the second common-source line. The second doped well is coupled to the second common-source line.

In an embodiment of the present invention, the first memory cell and the second memory cell are symmetric about the first common-source line. The third memory cell and the fourth memory cell are symmetric about the second common-source line. The second memory cell and the third memory cell are located between the first memory cell and the fourth memory cell.

In an embodiment of the present invention, the first memory cell, the second memory cell, the third memory cell, and the fourth memory cell further include a first gate dielectric block, a second gate dielectric block, a third gate dielectric block, a fourth gate dielectric block, a first conductive gate, a second conductive gate, a third conductive gate, a fourth conductive gate, a first heavily-doped area, a second heavily-doped area, and a third heavily-doped area. The first gate dielectric block, the second gate dielectric block, the third gate dielectric block, and the fourth gate dielectric block are respectively formed on the semiconductor region. The first conductive gate, the second conductive gate, the third conductive gate, and the fourth conductive gate are respectively formed on the first gate dielectric block, the second gate dielectric block, the third gate dielectric block, and the fourth gate dielectric block. The first conductive gate and the second conductive gate overlap the first doped well. The third conductive gate and the fourth conductive gate overlap the second doped well. The first heavily-doped area is formed in the semiconductor region. The first heavily-doped area and the first doped well are respectively formed on two opposite side of the semiconductor region, which is directly arranged under the first conductive gate. The first heavily-doped area is coupled to the first word bit line. The first heavily-doped area has the second conductivity type. The second heavily-doped area is formed in the semiconductor region. The second heavily-doped area and the second doped well are respectively formed on two opposite side of the semiconductor region, which is directly arranged under the second conductive gate. The second heavily-doped area is coupled to the second word bit line. The second heavily-doped area has the second conductivity type. The second heavily-doped area and the second doped well are respectively formed on two opposite side of the semiconductor region, which is directly arranged under the third conductive gate. The third heavily-doped area is formed in the semiconductor region. The third heavily-doped area and the second heavily-doped area are respectively formed on two opposite side of the semiconductor region, which is directly arranged under the fourth conductive gate. The third heavily-doped area is coupled to the first word bit line. The third heavily-doped area has the second conductivity type. The doping concentrations of the first heavily-doped area, the second heavily-doped area, and the third heavily-doped area are greater than those of the first doped well and the second doped well.

In an embodiment of the present invention, the first conductivity type is a P type and the second conductivity type is an N type.

In an embodiment of the present invention, when the first memory cell is selected to perform a programming activity, the semiconductor region is coupled to a grounding voltage, the first word bit line is coupled to a middle voltage or a high voltage, and the first common-source line is coupled to the grounding voltage, the middle voltage, or the high voltage. When the first memory cell is not selected to perform a programming activity, the semiconductor region is coupled to the grounding voltage, the first word bit line is coupled to the grounding voltage, and the first common-source line is coupled to a low voltage or electrically floating. When the first memory cell is selected to perform an erasing activity, the semiconductor region is coupled to the grounding voltage, the first word bit line is coupled to the grounding voltage, and the first common-source line is coupled to the high voltage. When the first memory cell is not selected to perform an erasing activity, the semiconductor region is coupled to the grounding voltage, the first word bit line is electrically floating or coupled to the low voltage, and the first common-source line is electrically floating. When the first memory cell is selected to perform a reading activity, the first word bit line is coupled to the low voltage and the semiconductor region and the first common-source line are coupled to the grounding voltage. When the first memory cell is not selected to perform a reading activity, the semiconductor region and the first word bit line are coupled to the grounding voltage and the first common-source line is coupled to the low voltage or electrically floating. The high voltage is greater than the middle voltage, the middle voltage is greater than the low voltage, and the low voltage is greater than the grounding voltage.

In an embodiment of the present invention, when the second memory cell is selected to perform a programming activity, the semiconductor region is coupled to a grounding voltage, the second word bit line is coupled to a middle voltage or a high voltage, and the first common-source line is coupled to the high voltage, the grounding voltage, or the middle voltage. When the second memory cell is not selected to perform a programming activity, the semiconductor region is coupled to the grounding voltage, the second word bit line is coupled to the grounding voltage, and the first common-source line is coupled to a low voltage or electrically floating. When the second memory cell is selected to perform an erasing activity, the semiconductor region is coupled to the grounding voltage, the second word bit line is coupled to the grounding voltage, and the first common-source line is coupled to the high voltage. When the second memory cell is not selected to perform an erasing activity, the semiconductor region is coupled to the grounding voltage, the second word bit line is electrically floating or coupled to the low voltage, and the first common-source line is electrically floating. When the second memory cell is selected to perform a reading activity, the second word bit line is coupled to the low voltage and the semiconductor region and the first common-source line are coupled to the grounding voltage. When the second memory cell is not selected to perform a reading activity, the semiconductor region and the second word bit line are coupled to the grounding voltage and the first common-source line is coupled to the low voltage or electrically floating. The high voltage is greater than the middle voltage, the middle voltage is greater than the low voltage, and the low voltage is greater than the grounding voltage.

In an embodiment of the present invention, when the third memory cell is selected to perform a programming activity, the semiconductor region is coupled to a grounding voltage, the second word bit line is coupled to a middle voltage or a high voltage, and the second common-source line is coupled to the high voltage, the grounding voltage, or the middle voltage. When the third memory cell is not selected to perform a programming activity, the semiconductor region is coupled to the grounding voltage, the second word bit line is coupled to the grounding voltage, and the second common-source line is coupled to a low voltage or electrically floating. When the third memory cell is selected to perform an erasing activity, the semiconductor region is coupled to the grounding voltage, the second word bit line is coupled to the grounding voltage, and the second common-source line is coupled to the high voltage. When the third memory cell is not selected to perform an erasing activity, the semiconductor region is coupled to the grounding voltage, the second word bit line is electrically floating or coupled to the low voltage, and the second common-source line is electrically floating. When the third memory cell is selected to perform a reading activity, the second word bit line is coupled to the low voltage and the semiconductor region and the second common-source line are coupled to the grounding voltage. When the third memory cell is not selected to perform a reading activity, the semiconductor region and the second word bit line are coupled to the grounding voltage and the second common-source line is coupled to the low voltage or electrically floating. The high voltage is greater than the middle voltage, the middle voltage is greater than the low voltage, and the low voltage is greater than the grounding voltage.

In an embodiment of the present invention, when the fourth memory cell is selected to perform a programming activity, the semiconductor region is coupled to a grounding voltage, the first word bit line is coupled to a middle voltage or a high voltage, and the second common-source line is coupled to the high voltage, the grounding voltage, or the middle voltage. When the fourth memory cell is not selected to perform a programming activity, the semiconductor region is coupled to the grounding voltage, the first word bit line is coupled to the grounding voltage, and the second common-source line is coupled to a low voltage or electrically floating. When the fourth memory cell is selected to perform an erasing activity, the semiconductor region is coupled to the grounding voltage, the first word bit line is coupled to the grounding voltage, and the second common-source line is coupled to the high voltage. When the fourth memory cell is not selected to perform an erasing activity, the semiconductor region is coupled to the grounding voltage, the first word bit line is electrically floating or coupled to the low voltage, and the second common-source line is electrically floating. When the fourth memory cell is selected to perform a reading activity, the first word bit line is coupled to the low voltage and the semiconductor region and the second common-source line are coupled to the grounding voltage. When the fourth memory cell is not selected to perform a reading activity, the semiconductor region and the first word bit line are coupled to the grounding voltage and the second common-source line is coupled to the low voltage or electrically floating. The high voltage is greater than the middle voltage, the middle voltage is greater than the low voltage, and the low voltage is greater than the grounding voltage.

In an embodiment of the present invention, the first conductivity type is an N type and the second conductivity type is a P type.

In an embodiment of the present invention, when the first memory cell is selected to perform a programming activity, the semiconductor region is coupled to a high voltage, the first word bit line is coupled to a middle voltage or a grounding voltage, and the first common-source line is coupled to the grounding voltage, the middle voltage, or the high voltage. When the first memory cell is not selected to perform a programming activity, the semiconductor region is coupled to the high voltage, the first word bit line is coupled to the high voltage, and the first common-source line is coupled to the middle voltage or electrically floating. When the first memory cell is selected to perform an erasing activity, the semiconductor region is coupled to the high voltage, the first word bit line is coupled to the high voltage, and the first common-source line is coupled to the grounding voltage. When the first memory cell is not selected to perform an erasing activity, the semiconductor region is coupled to the high voltage, the first word bit line is coupled to the middle voltage or electrically floating, and the first common-source line is electrically floating. When the first memory cell is selected to perform a reading activity, the semiconductor region and the first common-source line are coupled to the middle voltage and the first word bit line is coupled to a low voltage. When the first memory cell is not selected to perform a reading activity, the semiconductor region and the first word bit line are coupled to the middle voltage and the first common-source line is coupled to the low voltage or electrically floating. The high voltage is greater than the middle voltage, the middle voltage is greater than the low voltage, and the low voltage is greater than the grounding voltage.

In an embodiment of the present invention, when the second memory cell is selected to perform a programming activity, the semiconductor region is coupled to a high voltage, the second word bit line is coupled to a middle voltage or a grounding voltage, and the first common-source line is coupled to the grounding voltage, the middle voltage, or the high voltage. When the second memory cell is not selected to perform a programming activity, the semiconductor region is coupled to the high voltage, the second word bit line is coupled to the high voltage, and the first common-source line is coupled to the middle voltage or electrically floating. When the second memory cell is selected to perform an erasing activity, the semiconductor region is coupled to the high voltage, the second word bit line is coupled to the high voltage, and the first common-source line is coupled to the grounding voltage. When the second memory cell is not selected to perform an erasing activity, the semiconductor region is coupled to the high voltage, the second word bit line is coupled to the middle voltage or electrically floating, and the first common-source line is electrically floating. When the second memory cell is selected to perform a reading activity, the semiconductor region and the first common-source line are coupled to the middle voltage and the second word bit line is coupled to a low voltage. When the second memory cell is not selected to perform a reading activity, the semiconductor region and the second word bit line are coupled to the middle voltage and the first common-source line is coupled to the low voltage or electrically floating. The high voltage is greater than the middle voltage, the middle voltage is greater than the low voltage, and the low voltage is greater than the grounding voltage.

In an embodiment of the present invention, when the third memory cell is selected to perform a programming activity, the semiconductor region is coupled to a high voltage, the second word bit line is coupled to a middle voltage or a grounding voltage, and the second common-source line is coupled to the grounding voltage, the middle voltage, or the high voltage. When the third memory cell is not selected to perform a programming activity, the semiconductor region is coupled to the high voltage, the second word bit line is coupled to the high voltage, and the second common-source line is coupled to the middle voltage or electrically floating. When the third memory cell is selected to perform an erasing activity, the semiconductor region is coupled to the high voltage, the second word bit line is coupled to the high voltage, and the second common-source line is coupled to the grounding voltage. When the third memory cell is not selected to perform an erasing activity, the semiconductor region is coupled to the high voltage, the second word bit line is coupled to the middle voltage or electrically floating, and the second common-source line is electrically floating. When the third memory cell is selected to perform a reading activity, the semiconductor region and the second common-source line are coupled to the middle voltage and the second word bit line is coupled to a low voltage. When the third memory cell is not selected to perform a reading activity, the semiconductor region and the second word bit line are coupled to the middle voltage and the second common-source line is coupled to the low voltage or electrically floating. The high voltage is greater than the middle voltage, the middle voltage is greater than the low voltage, and the low voltage is greater than the grounding voltage.

In an embodiment of the present invention, when the fourth memory cell is selected to perform a programming activity, the semiconductor region is coupled to a high voltage, the first word bit line is coupled to a middle voltage or a grounding voltage, and the second common-source line is coupled to the grounding voltage, the middle voltage, or the high voltage. When the fourth memory cell is not selected to perform a programming activity, the semiconductor region is coupled to the high voltage, the first word bit line is coupled to the high voltage, and the second common-source line is coupled to the middle voltage or electrically floating. When the fourth memory cell is selected to perform an erasing activity, the semiconductor region is coupled to the high voltage, the first word bit line is coupled to the high voltage, and the second common-source line is coupled to the grounding voltage. When the fourth memory cell is not selected to perform an erasing activity, the semiconductor region is coupled to the high voltage, the first word bit line is coupled to the middle voltage or electrically floating, and the second common-source line is electrically floating. When the fourth memory cell is selected to perform a reading activity, the semiconductor region and the second common-source line are coupled to the middle voltage and the first word bit line is coupled to a low voltage. When the fourth memory cell is not selected to perform a reading activity, the semiconductor region and the first word bit line are coupled to the middle voltage and the second common-source line is coupled to the low voltage or electrically floating. The high voltage is greater than the middle voltage, the middle voltage is greater than the low voltage, and the low voltage is greater than the grounding voltage.

In an embodiment of the present invention, the semiconductor region is a semiconductor substrate or an epitaxial layer formed on a semiconductor substrate.

In an embodiment of the present invention, a read-only memory includes a field-effect transistor and a capacitor. The drain of the field-effect transistor is coupled to a word bit line and the source of the field-effect transistor is coupled to a common-source line. The word bit line is perpendicular to the common-source line. One terminal of the capacitor is coupled to the gate of the field-effect transistor and another terminal of the capacitor is coupled to the word bit line. The field-effect transistor and the capacitor, formed in a semiconductor region having a first conductivity type, commonly include a doped well having a second conductivity type opposite to the first conductivity type. The doped well is formed in the semiconductor region and coupled to the common-source line. The doped well overlaps the common-source line.

In an embodiment of the present invention, the field-effect transistor and the capacitor further include a gate dielectric block, a conductive gate, and a heavily-doped area. The gate dielectric block is formed on the semiconductor region. The conductive gate, formed on the gate dielectric block, overlaps the doped well. The heavily-doped area, formed in the semiconductor region, has a doping concentration greater than the doping concentration of the doped well. The heavily-doped area and the doped well are respectively formed on two opposite side of the semiconductor region, which is directly arranged under the conductive gate. The heavily-doped area is coupled to the word bit line. The heavily-doped area has the second conductivity type.

In an embodiment of the present invention, the first conductivity type is a P type and the second conductivity type is an N type.

In an embodiment of the present invention, when the field-effect transistor and the capacitor are selected to perform a programming activity, the semiconductor region is coupled to a grounding voltage, the word bit line is coupled to a middle voltage or a high voltage, and the common-source line is coupled to the grounding voltage, the middle voltage, or the high voltage. When the field-effect transistor and the capacitor are not selected to perform a programming activity, the semiconductor region is coupled to the grounding voltage, the word bit line is coupled to the grounding voltage, and the common-source line is coupled to a low voltage or electrically floating. When the field-effect transistor and the capacitor are selected to perform an erasing activity, the semiconductor region is coupled to the grounding voltage, the word bit line is coupled to the grounding voltage, and the common-source line is coupled to the high voltage. When the field-effect transistor and the capacitor are not selected to perform an erasing activity, the semiconductor region is coupled to the grounding voltage, the word bit line is electrically floating or coupled to the low voltage, and the common-source line is electrically floating. When the field-effect transistor and the capacitor are selected to perform a reading activity, the word bit line is coupled to the low voltage and the semiconductor region and the common-source line are coupled to the grounding voltage. When the field-effect transistor and the capacitor are not selected to perform a reading activity, the semiconductor region and the word bit line are coupled to the grounding voltage and the common-source line is coupled to the low voltage or electrically floating. The high voltage is greater than the middle voltage, the middle voltage is greater than the low voltage, and the low voltage is greater than the grounding voltage.

In an embodiment of the present invention, the first conductivity type is an N type and the second conductivity type is a P type.

In an embodiment of the present invention, when the field-effect transistor and the capacitor are selected to perform a programming activity, the semiconductor region is coupled to a high voltage, the word bit line is coupled to a middle voltage or a grounding voltage, and the common-source line is coupled to the grounding voltage, the middle voltage, or the high voltage. When the field-effect transistor and the capacitor are not selected to perform a programming activity, the semiconductor region is coupled to the high voltage, the word bit line is coupled to the high voltage, and the common-source line is coupled to the middle voltage or electrically floating. When the field-effect transistor and the capacitor are selected to perform an erasing activity, the semiconductor region is coupled to the high voltage, the word bit line is coupled to the high voltage, and the common-source line is coupled to the grounding voltage. When the field-effect transistor and the capacitor are not selected to perform an erasing activity, the semiconductor region is coupled to the high voltage, the word bit line is coupled to the middle voltage or electrically floating, and the common-source line is electrically floating. When the field-effect transistor and the capacitor are selected to perform a reading activity, the semiconductor region and the common-source line are coupled to the middle voltage and the word bit line is coupled to a low voltage. When the field-effect transistor and the capacitor are not selected to perform a reading activity, the semiconductor region and the word bit line are coupled to the middle voltage and the common-source line is coupled to the low voltage or electrically floating. The high voltage is greater than the middle voltage, the middle voltage is greater than the low voltage, and the low voltage is greater than the grounding voltage.

In an embodiment of the present invention, the semiconductor region is a semiconductor substrate or an epitaxial layer formed on a semiconductor substrate.

To sum up, the read-only memory array and the read-only memory thereof employ the doped well as the path of operating the source to withstand high voltages, thereby improving reliability, life, performance, and anti-interference capabilities.

Below, the embodiments are described in detail in cooperation with the drawings to make easily understood the technical contents, characteristics and accomplishments of the present invention.

### BRIEF DESCRIPTION OF THE DRAWINGS

FIG. 1 is a schematic diagram illustrating the circuit layout of a read-only memory array according to an embodiment of the present invention;

FIG. 2 is a schematic diagram illustrating the circuit layout of a sub-memory array according to an embodiment of the present invention;

FIG. 3 is a cross-sectional view of a first memory cell and a second memory cell according to an embodiment of the present invention;

FIG. 4 is a cross-sectional view of a third memory cell and a fourth memory cell according to an embodiment of the present invention;

FIG. 5 is a schematic diagram illustrating the equivalent circuit of a sub-memory array according to an embodiment of the present invention;

FIG. 6 is a schematic diagram illustrating the equivalent circuit of a sub-memory array according to another embodiment of the present invention;

FIG. 7 is a cross-sectional view of a first memory cell and a second memory cell according to another embodiment of the present invention;

FIG. 8 is a cross-sectional view of a third memory cell and a fourth memory cell according to another embodiment of the present invention; and

FIG. 9 is a schematic diagram illustrating the equivalent circuit of a read-only memory according to an embodiment of the present invention;

FIG. 10 is a schematic diagram illustrating the equivalent circuit of a read-only memory according to another embodiment of the present invention;

FIG. 11 is a schematic diagram illustrating the circuit layout of a read-only memory according to an embodiment of the present invention;

FIG. 12 is a cross-sectional view of a read-only memory according to an embodiment of the present invention; and

FIG. 13 is a cross-sectional view of a read-only memory according to another embodiment of the present invention.

### DETAILED DESCRIPTION OF THE INVENTION

Reference will now be made in detail to embodiments illustrated in the accompanying drawings. Wherever possible, the same reference numbers are used in the drawings and the description to refer to the same or like parts. In the drawings, the shape and thickness may be exaggerated for clarity and convenience. This description will be directed in particular to elements forming part of, or cooperating more directly with, methods and apparatus in accordance with the present disclosure. It is to be understood that elements not specifically shown or described may take various forms well known to those skilled in the art. Many alternatives and modifications will be apparent to those skilled in the art, once informed by the present disclosure.

Unless otherwise specified, some conditional sentences or words, such as “can”, “could”, “might”, or “may”, usually attempt to express what the embodiment in the present invention has, but it can also be interpreted as a feature, element, or step that may not be needed. In other embodiments, these features, elements, or steps may not be required.

Reference throughout this specification to “one embodiment” or “an embodiment” means that a particular feature, structure, or characteristic described in connection with the embodiment is included in at least one embodiment. Thus, the appearances of the phrases “in one embodiment” or “in an embodiment” in various places throughout this specification are not necessarily all referring to the same embodiment.

Certain terms are used throughout the description and the claims to refer to particular components. One skilled in the art appreciates that a component may be referred to using different names. This disclosure does not intend to distinguish between components that differ in name but in function. In the description and in the claims, the term “comprise” is used in an open-ended fashion, and thus should be interpreted to mean “include, but not limited to.” The phrases “be coupled to,” “couples to,” and “coupling to” are intended to encompass any indirect or direct connection. Accordingly, if this disclosure mentions that a first device is coupled with a second device, it means that the first device may be directly or indirectly connected to the second device through electrical connections, wireless communications, optical communications, or other signal connections with/without other intermediate devices or connection means.

The invention is particularly described with the following examples which are only for instance. Those skilled in the art will readily observe that numerous modifications and alterations of the device and method may be made while retaining the teachings of the invention. Accordingly, the following disclosure should be construed as limited only by the metes and bounds of the appended claims. In the whole patent application and the claims, except for clearly described content, the meaning of the articles “a” and “the” includes the meaning of “one or at least one” of the elements or components. Moreover, in the whole patent application and the claims, except that the plurality can be excluded obviously according to the context, the singular articles also contain the description for the plurality of elements or components. In the entire specification and claims, unless the contents clearly specify the meaning of some terms, the meaning of the article “wherein” includes the meaning of the articles “wherein” and “whereon”. The meanings of every term used in the present claims and specification refer to a usual meaning known to one skilled in the art unless the meaning is additionally annotated. Some terms used to describe the invention will be discussed to guide practitioners about the invention. The examples in the present specification do not limit the claimed scope of the invention.

In the following description, a read-only memory array and a read-only memory thereof will be provided, which employs a doped well as the path of operating a source to withstand high voltages, thereby improving reliability, life, performance, and anti-interference capabilities.

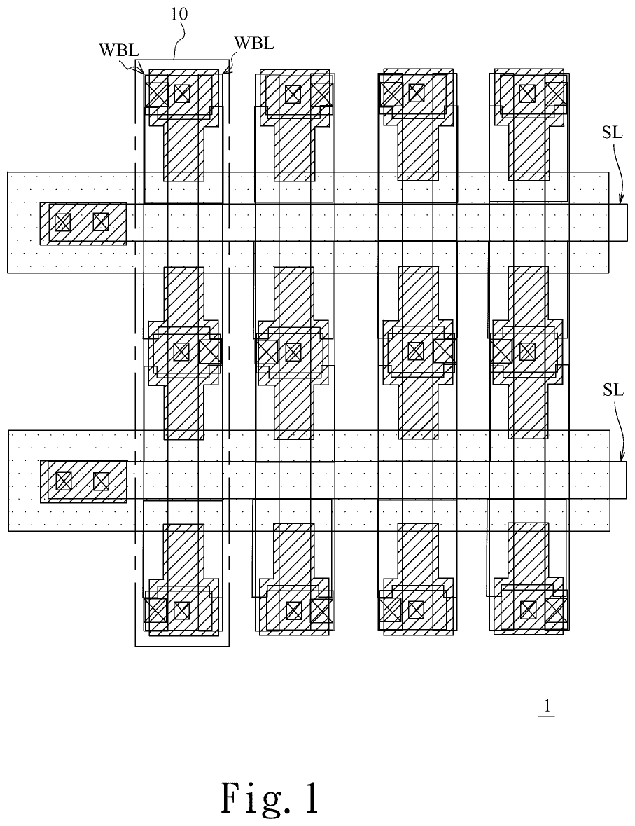

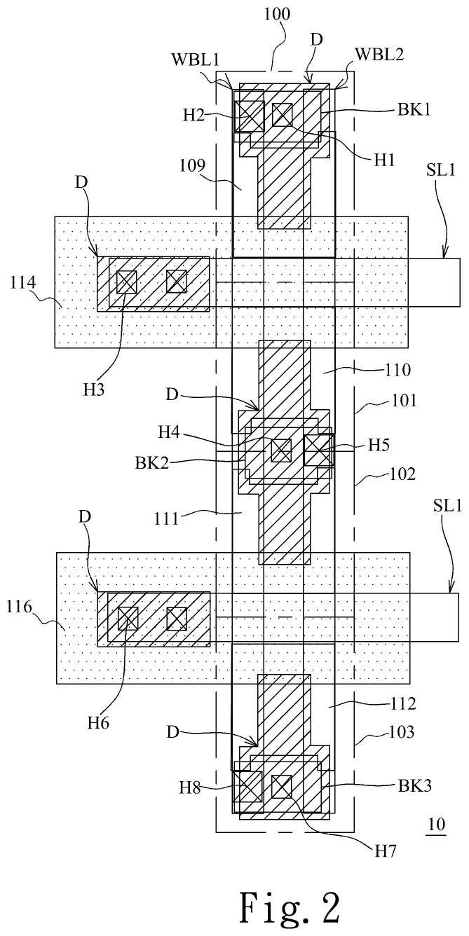

FIG. 1 is a schematic diagram illustrating the circuit layout of a read-only memory array according to an embodiment of the present invention. FIG. 2 is a schematic diagram illustrating the circuit layout of a sub-memory array according to an embodiment of the present invention. Referring to FIG. 1 and FIG. 2, a read-only memory array 1 of the present invention is introduced as follows. The read-only memory array 1 includes a plurality of common-source lines SL arranged in parallel, a plurality of word bit lines WBL arranged in parallel, and a plurality of sub-memory arrays 10. The common-source lines SL include a first common-source line SL1 and a second common-source line SL2. The word bit lines WBL are perpendicular to the common-source lines SL. The common-source lines SL are a part of a first conduction metal layer. The word bit lines WBL are a part of a second conduction metal layer. The word bit lines WBL include a first word bit line WBL1 and a second word bit line WBL2. Each sub-memory array 10 is coupled to two of the common-source lines SL and two of the word bit lines WBL. Each sub-memory array 10 includes a first memory cell 100, a second memory cell 101, a third memory cell 102, and a fourth memory cell 103. The control terminal of the first memory cell 100 is coupled to the first word bit line WBL1. The data terminal of the first memory cell 100 is coupled to the first common-source line SL1 and the first word bit line WBL1. The control terminal of the second memory cell 101 is coupled to the second word bit line WBL2. The data terminal of the second memory cell 101 is coupled to the first common-source line SL1 and the second word bit line WBL2. The control terminal of the third memory cell 102 is coupled to the second word bit line WBL2. The data terminal of the third memory cell 102 is coupled to the second common-source line SL2 and the second word bit line WBL2. The control terminal of the fourth memory cell 103 is coupled to the first word bit line WBL1. The data terminal of the fourth memory cell 103 is coupled to the second common-source line SL2 and the first word bit line WBL1. In some embodiments of the present invention, the first memory cell 100 and the second memory cell 101 are symmetric about the first common-source line SL1, the third memory cell 102 and the fourth memory cell 103 are symmetric about the second common-source line SL2, and the second memory cell 101 and the third memory cell 102 are located between the first memory cell 100 and the fourth memory cell 103.

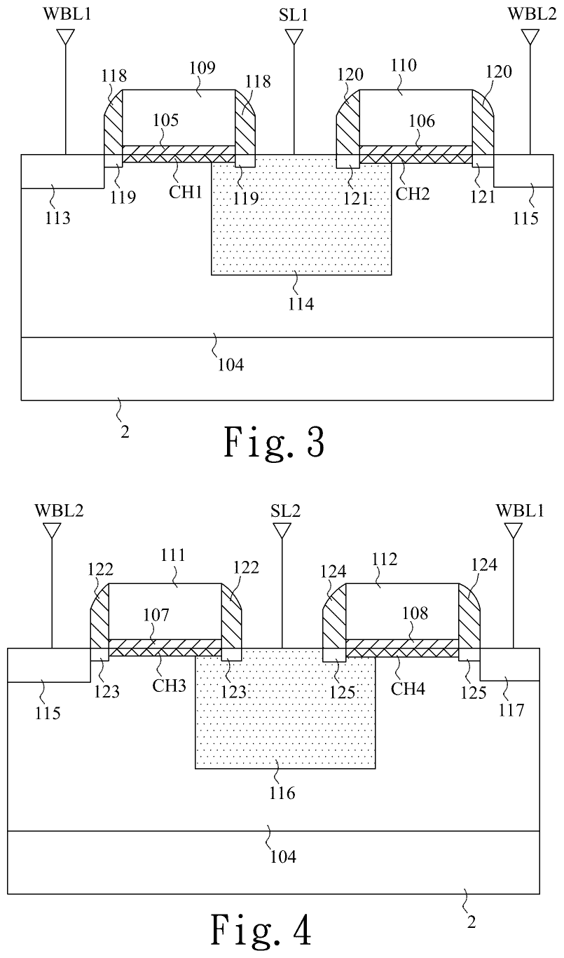

FIG. 3 is a cross-sectional view of a first memory cell and a second memory cell according to an embodiment of the present invention. FIG. 4 is a cross-sectional view of a third memory cell and a fourth memory cell according to an embodiment of the present invention. Referring to FIG. 2, FIG. 3, and FIG. 4, the first memory cell 100, the second memory cell 101, the third memory cell 102, and the fourth memory cell 103 are formed in a semiconductor region 104 having a first conductivity type. The semiconductor region 104 may be a semiconductor substrate or an epitaxial layer formed on a semiconductor substrate. In the embodiment, the semiconductor region 104 is exemplified by an epitaxial layer formed on a semiconductor substrate 2. The first memory cell 100, the second memory cell 101, the third memory cell 102, and the fourth memory cell 103 commonly include a first gate dielectric block 105, a second gate dielectric block 106, a third gate dielectric block 107, a fourth gate dielectric block 108, a first conductive gate 109, a second conductive gate 110, a third conductive gate 111, a fourth conductive gate 112, a first heavily-doped area 113, a first doped well 114, a second heavily-doped area 115, a second doped well 116, and a third heavily-doped area 117. The first gate dielectric block 105, the second gate dielectric block 106, the third gate dielectric block 107, and the fourth gate dielectric block 108 are a part of a dielectric layer D. The first conductive gate 109, the second conductive gate 110, the third conductive gate 111, and the fourth conductive gate 112 are a part of an electrode layer. The first gate dielectric block 105, the second gate dielectric block 106, the third gate dielectric block 107, and the fourth gate dielectric block 108 are respectively formed on the semiconductor region 104. The first conductive gate 109, the second conductive gate 110, the third conductive gate 111, and the fourth conductive gate 112 are respectively formed on the first gate dielectric block 105, the second gate dielectric block 106, the third gate dielectric block 107, and the fourth gate dielectric block 108. The first doped well 114 and the second doped well 116, having a second conductivity type opposite to the first conductivity type, are formed in the semiconductor region 104. The first doped well 114, overlapping the first common-source line SL1, is coupled to the first common-source line SL1. The second doped well 116, overlapping the second common-source line SL2, is coupled to the second common-source line SL2. The first conductive gate 109 and the second conductive gate 110 overlap the first doped well 114. The third conductive gate 111 and the fourth conductive gate 112 overlap the second doped well 116. The first heavily-doped area 113 is formed in the semiconductor region 104. The first heavily-doped area 113 and the first doped well 114 are respectively formed on two opposite side of the semiconductor region 104, which is directly arranged under the first conductive gate 109. The first heavily-doped area 113, coupled to the first word bit line WBL1, has the second conductivity type. In the embodiment, the first conductivity type is a P-type and the second conductivity type is an N type. A first conduction metal block BK1, a second conduction metal block BK2, and a third conduction metal block BK3 are a part of the first conduction metal layer. The electrode layer, the first conduction metal layer, and the second conduction metal layer are sequentially arranged from bottom to top. The second heavily-doped area 115 is formed in the semiconductor region 104. The second heavily-doped area 115 and the first doped well 114 are respectively formed on two opposite side of the semiconductor region 104, which is directly arranged under the second conductive gate 110. The second heavily-doped area 115 is coupled to the second word bit line WBL2. The second heavily-doped area 115 has the second conductivity type. The second heavily-doped area 115 and the second doped well 116 are respectively formed on two opposite side of the semiconductor region 104, which is directly arranged under the third conductive gate 111. The third heavily-doped area 117 is formed in the semiconductor region 104. The third heavily-doped area 117 and the second doped well 116 are respectively formed on two opposite side of the semiconductor region 104, which is directly arranged under the fourth conductive gate 112. The third heavily-doped area 117 is coupled to the first word bit line WBL1. The third heavily-doped area 117 has the second conductivity type. Besides, the doping concentrations of the first heavily-doped area 113, the second heavily-doped area 115, and the third heavily-doped area 117 are greater than those of the first doped well 114 and the second doped well 116. The read-only memory array employs the doped well as the path of operating a source to withstand high voltages, thereby improving reliability, life, performance, and anti-interference capabilities.

The first conduction metal block BK1 overlaps a first conduction via H1 and a second conduction via H2. The first word bit line WBL1 overlaps the second conduction via H2. The first conduction via H1 penetrates through the dielectric layer D. The first heavily-doped area 113 is coupled to the first word bit line WBL1 through the first conduction via H1, the first conduction block BK1, and the second conduction via H2 in sequence. The first common-source line SL1 overlaps a third conduction via H3. The third conduction via H3 penetrates through the dielectric layer D. The first doped well 114 is coupled to the first common-source SL1 through the third conduction via H3. Since the third conduction via H3 only provides voltage for the first common-source SL1 rather than connects to other components, the overall resistance of each sub-memory array 10 can be reduced. A fourth conduction via H4 penetrates through the dielectric layer D. The fourth conduction via H4 and a fifth conduction via H5 overlap the second conduction block BK2. The second heavily-doped area 115 is coupled to the second word bit line WBL2 through the fourth conduction via H4, the second conduction block BK2, and the fifth conduction via H5. The second common-source line SL2 overlaps a sixth conduction via H6. The sixth conduction via H6 penetrates through the dielectric layer D. The second doped well 116 is coupled to the second common-source line SL2 through the sixth conduction via H6. Since the sixth conduction via H6 only provides voltage for the second common-source line SL2 rather than connects to other components, the overall resistance of each sub-memory array 10 can be reduced. The third conduction block BK3 overlaps a seventh conduction via H7 and an eighth conduction via H8. The first word bit line WBL1 overlaps the eighth conduction via H8. The seventh conduction via H7 penetrates through the dielectric layer D. The third heavily-doped area 117 is coupled to the first word bit line WBL1 through the seventh conduction via H7, the third conduction metal BK3, and the eighth conduction via H8.

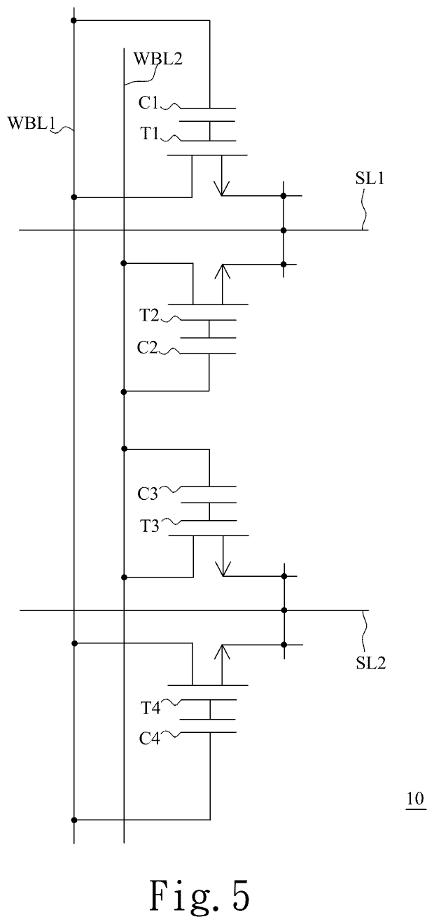

FIG. 5 is a schematic diagram illustrating the equivalent circuit of a sub-memory array according to an embodiment of the present invention. Please refer to FIG. 3, FIG. 4, and FIG. 5. The first heavily-doped area 113, the first doped well 114, the first gate dielectric block 105, the semiconductor region 104, and the first conductive gate 109 form a first metal-oxide-semiconductor field-effect transistor (MOSFET) T1. The first conductive gate 109 and the first heavily-doped area 113 form a first capacitor C1. The first heavily-doped area 113 is used as a drain and the first doped well 114 is used as a source. The two sidewalls of the first conductive gate 109 are respectively provided with two first sidewall spacers 118 that extend to the sidewall of the first gate dielectric block 105. There are two first lightly-doped drains (LDDs) 119 of the second conductivity type which are directly respectively formed under the two first sidewall spacers 118. When the first MOSFET T1 is turned on, a channel region CH1 is formed between the first LDDs 119.

The second heavily-doped area 115, the first doped well 114, the second gate dielectric block 106, the semiconductor region 104, and the second conductive gate 110 form a second metal-oxide-semiconductor field-effect transistor (MOSFET) T2. The second conductive gate 110 and the second heavily-doped area 115 form a second capacitor C2. The second heavily-doped area 115 is used as a drain and the first doped well 114 is used as a source. The two sidewalls of the second conductive gate 110 are respectively provided with two second sidewall spacers 120 that extend to the sidewall of the second gate dielectric block 106. There are two second lightly-doped drains (LDDs) 121 of the second conductivity type which are directly respectively formed under the two second sidewall spacers 120. When the second MOSFET T2 is turned on, a channel region CH2 is formed between the second LDDs 121.

The second heavily-doped area 115, the second doped well 116, the third gate dielectric block 107, the semiconductor region 104, and the third conductive gate 111 form a third metal-oxide-semiconductor field-effect transistor (MOSFET) T3. The third conductive gate 111 and the second heavily-doped area 115 form a third capacitor C3. The second heavily-doped area 115 is used as a drain and the second doped well 116 is used as a source. The two sidewalls of the third conductive gate 111 are respectively provided with two third sidewall spacers 122 that extend to the sidewall of the third gate dielectric block 107. There are two third lightly-doped drains (LDDs) 123 of the second conductivity type which are directly respectively formed under the two third sidewall spacers 122. When the third MOSFET T3 is turned on, a channel region CH3 is formed between the third LDDs 123.

The third heavily-doped area 117, the second doped well a 116, the fourth gate dielectric block 108, the semiconductor region 104, and the fourth conductive gate 112 form a fourth metal-oxide-semiconductor field-effect transistor (MOSFET) T4. The fourth conductive gate 112 and the third heavily-doped area 117 form a fourth capacitor C4. The third heavily-doped area 117 is used as a drain and the second doped well 116 is used as a source. The two sidewalls of the fourth conductive gate 112 are respectively provided with two fourth sidewall spacers 124 that extend to the sidewall of the fourth gate dielectric block 108. There are two fourth lightly-doped drains (LDDs) 125 of the second conductivity which are directly respectively formed under the two fourth sidewall spacers 124. When the fourth MOSFET T4 is turned on, a channel region CH4 is formed between the fourth LDDs 125.

The operation of the first memory cell 100 is introduced as follows, including those of programming, erasing, and reading activities. The common-source line or the word bit line is electrically floating or coupled to a high voltage, a middle voltage, or a grounding voltage based on the process characteristics.

When the first memory cell 100 is selected to perform a programming activity, the semiconductor region 104 is coupled to a grounding voltage, the first word bit line WBL1 is coupled to a middle voltage or a high voltage, and the first common-source line SL1 is coupled to the high voltage, the middle voltage, or the grounding voltage. When the first memory cell 100 is not selected to perform a programming activity, the semiconductor region 104 is coupled to the grounding voltage, the first word bit line WBL1 is coupled to the grounding voltage, and the first common-source line SL1 is coupled to the low voltage or electrically floating. When the first memory cell 100 is selected to perform an erasing activity, the semiconductor region 104 is coupled to the grounding voltage, the first word bit line WBL1 is coupled to the grounding voltage, and the first common-source line SL1 is coupled to the high voltage. When the first memory cell 100 is not selected to perform an erasing activity, the semiconductor region 104 is coupled to the grounding voltage, the first word bit line WBL1 is electrically floating or coupled to the low voltage, and the first common-source SL1 is electrically floating. When the first memory cell 100 is selected to perform a reading activity, the semiconductor region 104 and the first common-source line SL1 are coupled to the grounding voltage and the first word bit source line WBL1 is coupled to the low voltage. When the first memory cell 100 is not selected to perform a reading activity, the semiconductor region 104 and the first word bit line WBL1 are coupled to the grounding voltage and the first common-source line SL1 is coupled to the low voltage or electrically floating. In the foregoing operation, the high voltage is greater than the middle voltage, the middle voltage is greater than the low voltage, and the low voltage is greater than the grounding voltage. When the first memory cell 100 operates based on channel hot electron injection, the high voltage is slightly lower than the drain-to-source breakdown voltage of the first MOSFET T1. That is to say, the high voltage is equal to the drain-to-source breakdown voltage of the first MOSFET T1 minus the threshold voltage of the first MOSFET T1. The middle voltage is equal to the drain-to-source breakdown voltage of the first MOSFET T1×0.5. The low voltage is equal to the drain-to-source breakdown voltage of the first MOSFET T1×0.25. The grounding voltage is zero voltage. When the first memory cell 100 operates based on Fowler-Nordheim tunneling, the high voltage is equal to the breakdown voltage of an interface between the first doped well 114 and the semiconductor region 104. The middle voltage is equal to the drain-to-source breakdown voltage of the first MOSFET T1 minus the threshold voltage of the first MOSFET T1. The low voltage is equal to the drain-to-source breakdown voltage of the first MOSFET T1×0.25. The grounding voltage is zero voltage.

The operation of the second memory cell 101 is introduced as follows, including those of programming, erasing, and reading activities. The common-source line or the word bit line is electrically floating or coupled to a high voltage, a middle voltage, or a grounding voltage based on the process characteristics.

When the second memory cell 101 is selected to perform a programming activity, the semiconductor region 104 is coupled to a grounding voltage, the second word bit line WBL2 is coupled to a middle voltage or a high voltage, and the first common-source line SL1 is coupled to the high voltage, the middle voltage, or the grounding voltage. When the second memory cell 101 is not selected to perform a programming activity, the semiconductor region 104 is coupled to the grounding voltage, the second word bit line WBL2 is coupled to the grounding voltage, and the first common-source line SL1 is coupled to the low voltage or electrically floating. When the second memory cell 101 is selected to perform an erasing activity, the semiconductor region 104 is coupled to the grounding voltage, the second word bit line WBL2 is coupled to the grounding voltage, and the first common-source line SL1 is coupled to the high voltage. When the second memory cell 101 is not selected to perform an erasing activity, the semiconductor region 104 is coupled to the grounding voltage, the second word bit line WBL2 is electrically floating or coupled to the low voltage, and the first common-source SL1 is electrically floating. When the second memory cell 101 is selected to perform a reading activity, the semiconductor region 104 and the first common-source line SL1 are coupled to the grounding voltage and the second word bit line WBL2 is coupled to the low voltage. When the second memory cell 101 is not selected to perform a reading activity, the semiconductor region 104 and the second word bit line WBL2 are coupled to the grounding voltage and the first common-source line SL1 is coupled to the low voltage or electrically floating. In the foregoing operation, the high voltage is greater than the middle voltage, the middle voltage is greater than the low voltage, and the low voltage is greater than the grounding voltage. When the second memory cell 101 operates based on channel hot electron injection, the high voltage is slightly lower than the drain-to-source breakdown voltage of the second MOSFET T2. That is to say, the high voltage is equal to the drain-to-source breakdown voltage of the second MOSFET T2 minus the threshold voltage of the second MOSFET T2. The middle voltage is equal to the drain-to-source breakdown voltage of the second MOSFET T2×0.5. The low voltage is equal to the drain-to-source breakdown voltage of the second MOSFET T2×0.25. The grounding voltage is zero voltage. When the second memory cell 101 operates based on Fowler-Nordheim tunneling, the high voltage is equal to the breakdown voltage of an interface between the first doped well 114 and the semiconductor region 104. The middle voltage is equal to the drain-to-source breakdown voltage of the second MOSFET T2 minus the threshold voltage of the second MOSFET T2. The low voltage is equal to the drain-to-source breakdown voltage of the second MOSFET T2×0.25. The grounding voltage is zero voltage.

The operation of the third memory cell 102 is introduced as follows, including those of programming, erasing, and reading activities. The common-source line or the word bit line is electrically floating or coupled to a high voltage, a middle voltage, or a grounding voltage based on the process characteristics.

When the third memory cell 102 is selected to perform a programming activity, the semiconductor region 104 is coupled to a grounding voltage, the second word bit line WBL2 is coupled to a middle voltage or a high voltage, and the second common-source line SL2 is coupled to the high voltage, the middle voltage, or the grounding voltage. When the third memory cell 102 is not selected to perform a programming activity, the semiconductor region 104 is coupled to the grounding voltage, the second word bit line WBL2 is coupled to the grounding voltage, and the second common-source line SL2 is coupled to the low voltage or electrically floating. When the third memory cell 102 is selected to perform an erasing activity, the semiconductor region 104 is coupled to the grounding voltage, the second word bit line WBL2 is coupled to the grounding voltage, and the second common-source line SL2 is coupled to the high voltage. When the third memory cell 102 is not selected to perform an erasing activity, the semiconductor region 104 is coupled to the grounding voltage, the second word bit line WBL2 is electrically floating or coupled to the low voltage, and the second common-source SL2 is electrically floating. When the third memory cell 102 is selected to perform a reading activity, the semiconductor region 104 and the second common-source line SL2 are coupled to the grounding voltage and the second word bit line WBL2 is coupled to the low voltage. When the third memory cell 102 is not selected to perform a reading activity, the semiconductor region 104 and the second word bit line WBL2 are coupled to the grounding voltage and the second common-source line SL2 is coupled to the low voltage or electrically floating. In the foregoing operation, the high voltage is greater than the middle voltage, the middle voltage is greater than the low voltage, and the low voltage is greater than the grounding voltage. When the third memory cell 102 operates based on channel hot electron injection, the high voltage is slightly lower than the drain-to-source breakdown voltage of the third MOSFET T3. That is to say, the high voltage is equal to the drain-to-source breakdown voltage of the third MOSFET T3 minus the threshold voltage of the third MOSFET T3. The middle voltage is equal to the drain-to-source breakdown voltage of the third MOSFET T3×0.5. The low voltage is equal to the drain-to-source breakdown voltage of the third MOSFET T3×0.25. The grounding voltage is zero voltage. When the third memory cell 102 operates based on Fowler-Nordheim tunneling, the high voltage is equal to the breakdown voltage of an interface between the second doped well 116 and the semiconductor region 104. The middle voltage is equal to the drain-to-source breakdown voltage of the third MOSFET T3 minus the threshold voltage of the third MOSFET T3. The low voltage is equal to the drain-to-source breakdown voltage of the third MOSFET T3×0.25. The grounding voltage is zero voltage.

The operation of the fourth memory cell 103 is introduced as follows, including those of programming, erasing, and reading activities. The common-source line or the word bit line is electrically floating or coupled to a high voltage, a middle voltage, or a grounding voltage based on the process characteristics.

When the fourth memory cell 103 is selected to perform a programming activity, the semiconductor region 104 is coupled to a grounding voltage, the first word bit line WBL1 is coupled to a middle voltage or a high voltage, and the second common-source line SL2 is coupled to the high voltage, the middle voltage, or the grounding voltage. When the fourth memory cell 103 is not selected to perform a programming activity, the semiconductor region 104 is coupled to the grounding voltage, the first word bit line WBL1 is coupled to the grounding voltage, and the second common-source line SL2 is coupled to a low voltage or electrically floating. When the fourth memory cell 103 is selected to perform an erasing activity, the semiconductor region 104 is coupled to the grounding voltage, the first word bit line WBL1 is coupled to the grounding voltage, and the second common-source line SL2 is coupled to the high voltage. When the fourth memory cell 103 is not selected to perform an erasing activity, the semiconductor region 104 is coupled to the grounding voltage, the first word bit line WBL1 is electrically floating or coupled to the low voltage, and the second common-source SL2 is electrically floating. When the fourth memory cell 103 is selected to perform a reading activity, the semiconductor region 104 and the second common-source line SL2 are coupled to the grounding voltage and the first word bit line WBL1 is coupled to the low voltage. When the fourth memory cell 103 is not selected to perform a reading activity, the semiconductor region 104 and the first word bit line WBL1 are coupled to the grounding voltage and the second common-source line SL2 is coupled to the low voltage or electrically floating. In the foregoing operation, the high voltage is greater than the middle voltage, the middle voltage is greater than the low voltage, and the low voltage is greater than the grounding voltage. When the fourth memory cell 103 based on channel hot electron injection, the high voltage is slightly lower than the drain-to-source breakdown voltage of the fourth MOSFET T4. That is to say, the high voltage is equal to the drain-to-source breakdown voltage of the fourth MOSFET T4 minus the threshold voltage of the fourth MOSFET T4. The middle voltage is equal to the drain-to-source breakdown voltage of the fourth MOSFET T4×0.5. The low voltage is equal to the drain-to-source breakdown voltage of the fourth MOSFET T4×0.25. The grounding voltage is zero voltage. When the fourth memory cell 103 operates based on Fowler-Nordheim tunneling, the high voltage is equal to the breakdown voltage of an interface between the second doped well 116 and the semiconductor region 104. The middle voltage is equal to the drain-to-source breakdown voltage of the fourth MOSFET T4 minus the threshold voltage of the fourth MOSFET T4. The low voltage is equal to the drain-to-source breakdown voltage of the fourth MOSFET T4×0.25. The grounding voltage is zero voltage.

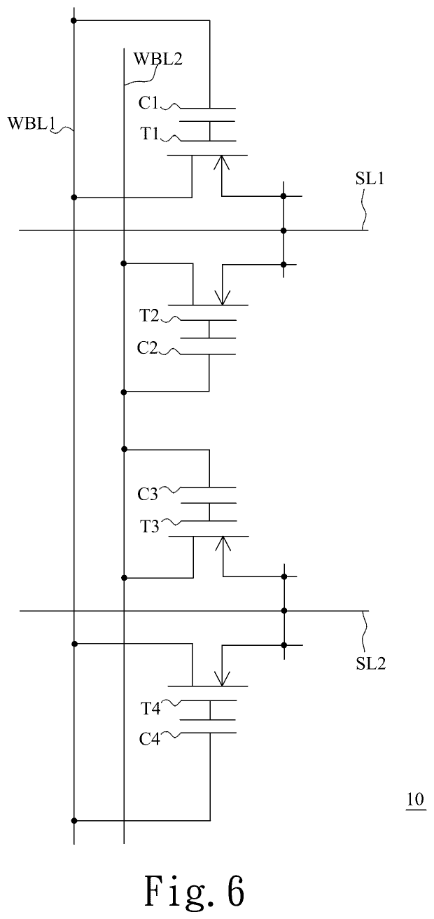

FIG. 6 is a schematic diagram illustrating the equivalent circuit of a sub-memory array according to another embodiment of the present invention. Please refer to FIG. 3, FIG. 4, and FIG. 6. In the embodiment, the first conductivity type is an N type and the second conductivity type is a P type. The operation of the first memory cell 100 is introduced as follows, including those of programming, erasing, and reading activities. The common-source line or the word bit line is electrically floating or coupled to a high voltage, a middle voltage, or a grounding voltage based on the process characteristics.

When the first memory cell 100 is selected to perform a programming activity, the semiconductor region 104 is coupled to a high voltage, the first word bit line WBL1 is coupled to a middle voltage or a grounding voltage, and the first common-source line SL1 is coupled to the grounding voltage, the middle voltage, or the high voltage. When the first memory cell 100 is not selected to perform a programming activity, the semiconductor region 104 is coupled to the high voltage, the first word bit line WBL1 is coupled to the high voltage, and the first common-source line SL1 is coupled to the middle voltage or electrically floating. When the first memory cell 100 is selected to perform an erasing activity, the semiconductor region 104 is coupled to the high voltage, the first word bit line WBL1 is coupled to the high voltage, and the first common-source line SL1 is coupled to the grounding voltage. When the first memory cell 100 is not selected to perform an erasing activity, the semiconductor region 104 is coupled to the high voltage, the first word bit line WBL1 is coupled to the middle voltage or electrically floating, and the first common-source SL1 is electrically floating. When the first memory cell 100 is selected to perform a reading activity, the semiconductor region 104 and the first common-source line SL1 are coupled to the middle voltage and the first word bit line WBL1 is coupled to the low voltage. When the first memory cell 100 is not selected to perform a reading activity, the semiconductor region 104 and the first word bit line WBL1 are coupled to the middle voltage and the first common-source line SL1 is coupled to the low voltage or electrically floating. In the foregoing operation, the high voltage is greater than the middle voltage, the middle voltage is greater than the low voltage, and the low voltage is greater than the grounding voltage. When the first memory cell 100 operates based on channel hot electron injection, the high voltage is slightly lower than the source-to-drain breakdown voltage of the first MOSFET T1. That is to say, the high voltage is equal to the source-to-drain breakdown voltage of the first MOSFET T1 plus the threshold voltage of the first MOSFET T1. The middle voltage is equal to the source-to-drain breakdown voltage of the first MOSFET T1×0.5. The low voltage is equal to the source-to-drain breakdown voltage of the first MOSFET T1×0.25.

The grounding voltage is zero voltage. When the first memory cell 100 operates based on Fowler-Nordheim tunneling, the high voltage is equal to the breakdown voltage of an interface between the first doped well 114 and the semiconductor region 104. The middle voltage is equal to the source-to-drain breakdown voltage of the first MOSFET T1 plus the threshold voltage of the first MOSFET T1. The low voltage is equal to the source-to-drain breakdown voltage of the first MOSFET T1×0.25. The grounding voltage is zero voltage.

The operation of the second memory cell 101 is introduced as follows, including those of programming, erasing, and reading activities. The common-source line or the word bit line is electrically floating or coupled to a high voltage, a middle voltage, or a grounding voltage based on the process characteristics.

When the second memory cell 101 is selected to perform a programming activity, the semiconductor region 104 is coupled to a high voltage, the second word bit line WBL2 is coupled to a middle voltage or a grounding voltage, and the first common-source line SL1 is coupled to the grounding voltage, the middle voltage, or the high voltage. When the second memory cell 101 is not selected to perform a programming activity, the semiconductor region 104 is coupled to the high voltage, the second word bit line WBL2 is coupled to the high voltage, and the first common-source line SL1 is coupled to the middle voltage or electrically floating. When the second memory cell 101 is selected to perform an erasing activity, the semiconductor region 104 is coupled to the high voltage, the second word bit line WBL2 is coupled to the high voltage, and the first common-source line SL1 is coupled to the grounding voltage. When the second memory cell 101 is not selected to perform an erasing activity, the semiconductor region 104 is coupled to the high voltage, the second word bit line WBL2 is coupled to the middle voltage or electrically floating, and the first common-source SL1 is electrically floating. When the second memory cell 101 is selected to perform a reading activity, the semiconductor region 104 and the first common-source line SL1 are coupled to the middle voltage and the second word bit line WBL2 is coupled to the low voltage. When the second memory cell 101 is not selected to perform a reading activity, the semiconductor region 104 and the second word bit line WBL2 are coupled to the middle voltage and the first common-source line SL1 is coupled to the low voltage or electrically floating. In the foregoing operation, the high voltage is greater than the middle voltage, the middle voltage is greater than the low voltage, and the low voltage is greater than the grounding voltage. When the second memory cell 101 operates based on channel hot electron injection, the high voltage is slightly lower than the source-to-drain breakdown voltage of the second MOSFET T2. That is to say, the high voltage is equal to the source-to-drain breakdown voltage of the second MOSFET T2 plus the threshold voltage of the second MOSFET T2. The middle voltage is equal to the source-to-drain breakdown voltage of the second MOSFET T2×0.5. The low voltage is equal to the source-to-drain breakdown voltage of the second MOSFET T2×0.25. The grounding voltage is zero voltage. When the second memory cell 101 operates based on Fowler-Nordheim tunneling, the high voltage is equal to the breakdown voltage of an interface between the first doped well 114 and the semiconductor region 104. The middle voltage is equal to the source-to-drain breakdown voltage of the second MOSFET T2 plus the threshold voltage of the second MOSFET T2. The low voltage is equal to the source-to-drain breakdown voltage of the second MOSFET T2×0.25. The grounding voltage is zero voltage.

The operation of the third memory cell 102 is introduced as follows, including those of programming, erasing, and reading activities. The common-source line or the word bit line is electrically floating or coupled to a high voltage, a middle voltage, or a grounding voltage based on the process characteristics.

When the third memory cell 102 is selected to perform a programming activity, the semiconductor region 104 is coupled to a high voltage, the second word bit line WBL2 is coupled to a middle voltage or a grounding voltage, and the second common-source line SL2 is coupled to the grounding voltage, the middle voltage, or the high voltage. When the third memory cell 102 is not selected to perform a programming activity, the semiconductor region 104 is coupled to the high voltage, the second word bit line WBL2 is coupled to the high voltage, and the second common-source line SL2 is coupled to the middle voltage or electrically floating. When the third memory cell 102 is selected to perform an erasing activity, the semiconductor region 104 is coupled to the high voltage, the second word bit line WBL2 is coupled to the high voltage, and the second common-source line SL2 is coupled to the grounding voltage. When the third memory cell 102 is not selected to perform an erasing activity, the semiconductor region 104 is coupled to the high voltage, the second word bit line WBL2 is coupled to the middle voltage or electrically floating, and the second common-source SL2 is electrically floating. When the third memory cell 102 is selected to perform a reading activity, the semiconductor region 104 and the second common-source line SL2 are coupled to the middle voltage and the second word bit line WBL2 is coupled to the low voltage. When the third memory cell 102 is not selected to perform a reading activity, the semiconductor region 104 and the second word bit line WBL2 are coupled to the middle voltage and the second common-source line SL2 is coupled to the low voltage or electrically floating. In the foregoing operation, the high voltage is greater than the middle voltage, the middle voltage is greater than the low voltage, and the low voltage is greater than the grounding voltage. When the third memory cell 102 operates based on channel hot electron injection, the high voltage is slightly lower than the source-to-drain breakdown voltage of the third MOSFET T3. That is to say, the high voltage is equal to the source-to-drain breakdown voltage of the third MOSFET T3 plus the threshold voltage of the third MOSFET T3. The middle voltage is equal to the source-to-drain breakdown voltage of the third MOSFET T3×0.5. The low voltage is equal to the source-to-drain breakdown voltage of the third MOSFET T3×0.25. The grounding voltage is zero voltage. When the third memory cell 102 operates based on Fowler-Nordheim tunneling, the high voltage is equal to the breakdown voltage of an interface between the second doped well 116 and the semiconductor region 104. The middle voltage is equal to the source-to-drain breakdown voltage of the third MOSFET T3 plus the threshold voltage of the third MOSFET T3. The low voltage is equal to the source-to-drain breakdown voltage of the third MOSFET T3×0.25. The grounding voltage is zero voltage.

The operation of the fourth memory cell 103 is introduced as follows, including those of programming, erasing, and reading activities. The common-source line or the word bit line is electrically floating or coupled to a high voltage, a middle voltage, or a grounding voltage based on the process characteristics.

When the fourth memory cell 103 is selected to perform a programming activity, the semiconductor region 104 is coupled to a high voltage, the first word bit line WBL1 is coupled to a middle voltage or a grounding voltage, and the second common-source line SL2 is coupled to the grounding voltage, the middle voltage, or the high voltage. When the fourth memory cell 103 is not selected to perform a programming activity, the semiconductor region 104 is coupled to the high voltage, the first word bit line WBL1 is coupled to the high voltage, and the second common-source line SL2 is coupled to the middle voltage or electrically floating. When the fourth memory cell 103 is selected to perform an erasing activity, the semiconductor region 104 is coupled to the high voltage, the first word bit line WBL1 is coupled to the high voltage, and the second common-source line SL2 is coupled to the grounding voltage. When the fourth memory cell 103 is not selected to perform an erasing activity, the semiconductor region 104 is coupled to the high voltage, the first word bit line WBL1 is coupled to the middle voltage or electrically floating, and the second common-source SL2 is electrically floating. When the fourth memory cell 103 is selected to perform a reading activity, the semiconductor region 104 and the second common-source line SL2 are coupled to the middle voltage and the first word bit line WBL1 is coupled to the low voltage. When the fourth memory cell 103 is not selected to perform a reading activity, the semiconductor region 104 and the first word bit line WBL1 are coupled to the middle voltage and the second common-source line SL2 is coupled to the low voltage or electrically floating. In the foregoing operation, the high voltage is greater than the middle voltage, the middle voltage is greater than the low voltage, and the low voltage is greater than the grounding voltage. When the fourth memory cell 103 operates based on channel hot electron injection, the high voltage is slightly lower than the source-to-drain breakdown voltage of the fourth MOSFET T4. That is to say, the high voltage is equal to the source-to-drain breakdown voltage of the fourth MOSFET T4 plus the threshold voltage of the fourth MOSFET T4. The middle voltage is equal to the source-to-drain breakdown voltage of the fourth MOSFET T4×0.5. The low voltage is equal to the source-to-drain breakdown voltage of the fourth MOSFET T4×0.25. The grounding voltage is zero voltage. When the fourth memory cell 103 operates based on Fowler-Nordheim tunneling, the high voltage is equal to the breakdown voltage of an interface between the second doped well 116 and the semiconductor region 104. The middle voltage is equal to the source-to-drain breakdown voltage of the fourth MOSFET T4 plus the threshold voltage of the fourth MOSFET T4. The low voltage is equal to the source-to-drain breakdown voltage of the fourth MOSFET T4×0.25. The grounding voltage is zero voltage.

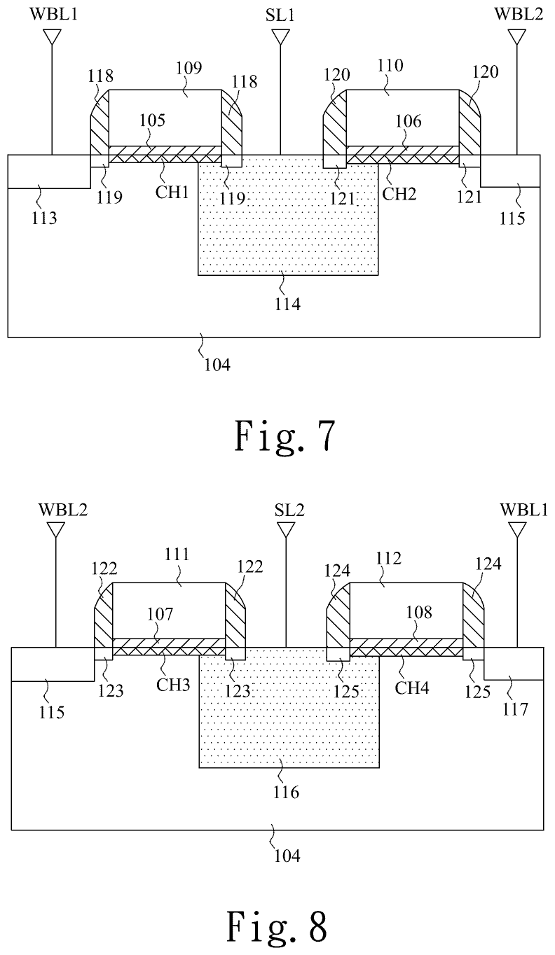

FIG. 7 is a cross-sectional view of a first memory cell and a second memory cell according to another embodiment of the present invention. FIG. 8 is a cross-sectional view of a third memory cell and a fourth memory cell according to another embodiment of the present invention. Referring to FIG. 7 and FIG. 8, the first memory cell 100, the second memory cell 101, the third memory cell 102, and the fourth memory cell 103 are formed in the semiconductor region 104 implemented with a semiconductor substrate. The other structures of the first memory cell 100, the second memory cell 101, the third memory cell 102, and the fourth memory cell 103 have been described previously so it will not be reiterated.

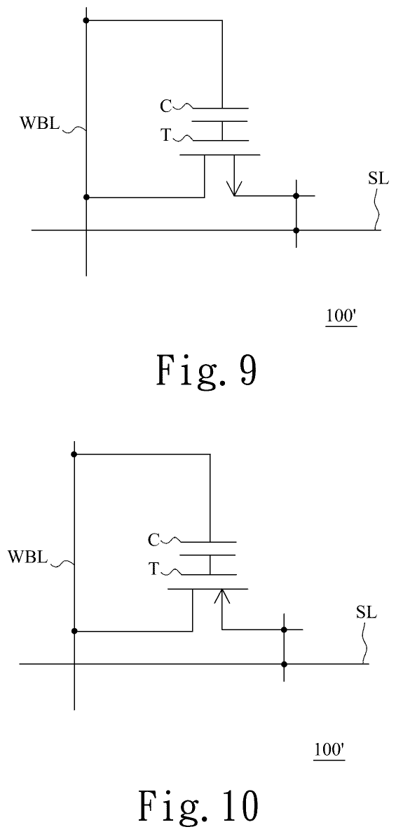

FIG. 9 is a schematic diagram illustrating the equivalent circuit of a read-only memory according to an embodiment of the present invention. FIG. 10 is a schematic diagram illustrating the equivalent circuit of a read-only memory according to another embodiment of the present invention. Please refer to FIG. 9 and FIG. 10. A read-only memory 100′ is introduced as follows. The read-only memory 100′ includes a field-effect transistor T and a capacitor C. The field-effect transistor T may be a P-channel metal-oxide-semiconductor field-effect transistor or an N-channel metal-oxide-semiconductor field-effect transistor. The drain of the field-effect transistor T is coupled to a word bit line WBL and the source of the field-effect transistor T is coupled to a common-source line SL. The word bit line WBL is perpendicular to the common-source line SL. One terminal of the capacitor C is coupled to the gate of the field-effect transistor T and another terminal of the capacitor C is coupled to the word bit line WBL.

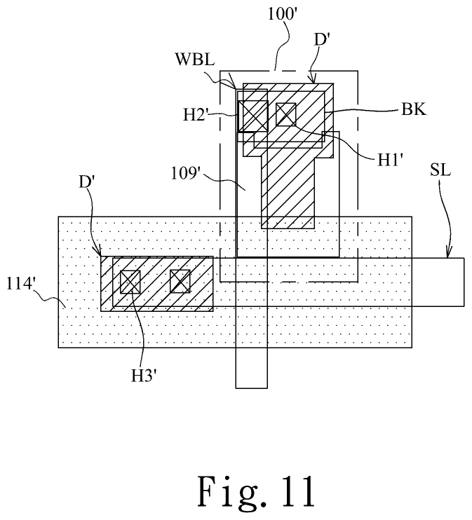

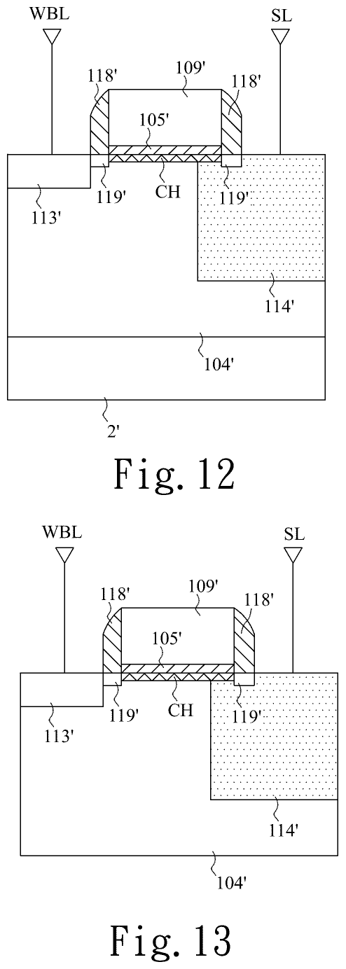

FIG. 11 is a schematic diagram illustrating the circuit layout of a read-only memory according to an embodiment of the present invention. FIG. 12 is a cross-sectional view of a read-only memory according to an embodiment of the present invention. Please refer to FIG. 11 and FIG. 12. The field-effect transistor T and the capacitor C are formed in a semiconductor region 104′ having a first conductivity type. The semiconductor region 104′ is a semiconductor substrate or an epitaxial layer formed on a semiconductor substrate. In the embodiment, the semiconductor region 104′ is an epitaxial layer formed on a semiconductor substrate 2′. The field-effect transistor T and the capacitor C commonly include a gate dielectric block 105′, a conductive gate 109′, a heavily-doped area 113′, and a doped well 114′. The gate dielectric block 105′ is a part of a dielectric layer D′. The conductive gate 109′ is a part of an electrode layer. The common-source line SL and a conduction block BK are a part of a first conduction metal layer. The word bit line WBL is a part of a second conduction metal layer. The heavily-doped area 113′ and the doped well 114′ have a second conductivity type opposite to the first conductivity type. The doped well 114′, formed in the semiconductor region 104′ and coupled to the common-source line SL, overlaps the common-source line SL. The gate dielectric block 105′ is formed on the semiconductor region 104′. The conductive gate 109′, formed on the gate dielectric block 105′, overlaps the doped well 114′. The heavily-doped area 113′ is formed in the semiconductor region 104′. The doping concentration of the heavily-doped area 113′ is greater than that of the doped well 114′. The heavily-doped area 113′ and the doped well 114′ are respectively formed on two opposite side of the semiconductor region 104′, which is directly arranged under the conductive gate 109′. The heavily-doped area 113′ is coupled to the word bit line WBL. The electrode layer, the first conduction metal layer, and the second conduction metal layer are formed from bottom to top.

The conduction block BK overlaps a first conduction via H1′ and a second conduction via H2′. The word bit lien WBL overlaps the second conduction via H2′. The first conduction via H1′ penetrates through the dielectric layer D′. The heavily-doped area 113′ is coupled to the word bit line WBL through the first conduction via H1′, the conduction block BK, and the second conduction via H2′ in sequence. The common-source line SL overlaps a third conduction via H3′. The third conduction via H3′ penetrates through the dielectric layer D′. The doped well 114′ is coupled to the common-source SL through the third conduction via H3′. Since the third conduction via H3′ only provides voltage for the common-source SL rather than connects to other components, the overall resistance of the read-only memory 100′ can be reduced.

The heavily-doped area 113′, the doped well 114′, the gate dielectric block 105′, the semiconductor region 104′, and the conductive gate 109′ form a metal-oxide-semiconductor field-effect transistor (MOSFET) T. The conductive gate 109′ and the heavily-doped area 113′ form a capacitor C. The heavily-doped area 113′ is used as a drain and the doped well 114′ is used as a source. The two sidewalls of the conductive gate 109′ are respectively provided with two sidewall spacers 118′ that extend to the sidewall of the gate dielectric block 105′. There are two lightly-doped drains (LDDs) 119′ of the second conductivity type which are directly respectively formed under the two sidewall spacers 118′. When the MOSFET T is turned on, a channel region CH is formed between the LDDs 119′.

Please refer to FIG. 9 and FIG. 12. In an embodiment, the first conductivity type is a P type and the second conductivity type is an N type. When the field-effect transistor T and the capacitor C are selected to perform a programming activity, the semiconductor region 104′ is coupled to a grounding voltage, the word bit line WBL is coupled to a middle voltage or a high voltage, and the common-source line SL is coupled to the grounding voltage, the middle voltage, or the high voltage. When the field-effect transistor T and the capacitor C are not selected to perform a programming activity, the semiconductor region 104′ is coupled to the grounding voltage, the word bit line WBL is coupled to the grounding voltage, and the common-source line SL is coupled to a low voltage or electrically floating. When the field-effect transistor T and the capacitor C are selected to perform an erasing activity, the semiconductor region 104′ is coupled to the grounding voltage, the word bit line WBL is coupled to the grounding voltage, and the common-source line SL is coupled to the high voltage. When the field-effect transistor T and the capacitor C are not selected to perform an erasing activity, the semiconductor region 104′ is coupled to the grounding voltage, the word bit line WBL is electrically floating or coupled to the low voltage, and the common-source line SL is electrically floating. When the field-effect transistor T and the capacitor C are selected to perform a reading activity, the word bit line WBL is coupled to the low voltage and the semiconductor region 104′ and the common-source line SL are coupled to the grounding voltage. When the field-effect transistor T and the capacitor C are not selected to perform a reading activity, the semiconductor region 104′ and the word bit line WBL are coupled to the grounding voltage and the common-source line SL is coupled to the low voltage or electrically floating. The high voltage is greater than the middle voltage, the middle voltage is greater than the low voltage, and the low voltage is greater than the grounding voltage. When the read-only memory 100′ operates based on channel hot electron injection, the high voltage is slightly lower than the drain-to-source breakdown voltage of the MOSFET T. That is to say, the high voltage is equal to the drain-to-source breakdown voltage of the MOSFET T minus the threshold voltage of the MOSFET T. The middle voltage is equal to the drain-to-source breakdown voltage of the MOSFET T×0.5. The low voltage is equal to the drain-to-source breakdown voltage of the MOSFET T×0.25. The grounding voltage is zero voltage. When the read-only memory 100′ operates based on Fowler-Nordheim tunneling, the high voltage is equal to the breakdown voltage of an interface between the doped well 114′ and the semiconductor region 104′. The middle voltage is equal to the drain-to-source breakdown voltage of the MOSFET T minus the threshold voltage of the MOSFET T. The low voltage is equal to the drain-to-source breakdown voltage of the MOSFET T×0.25. The grounding voltage is zero voltage.

Please refer to FIG. 10 and FIG. 12. In an embodiment, the first conductivity type is an N type and the second conductivity type is a P type. When the field-effect transistor T and the capacitor C are selected to perform a programming activity, the semiconductor region 104′ is coupled to a high voltage, the word bit line WBL is coupled to a middle voltage or a grounding voltage, and the common-source line SL is coupled to the grounding voltage, the middle voltage, or the high voltage. When the field-effect transistor T and the capacitor C are not selected to perform a programming activity, the semiconductor region 104′ is coupled to the high voltage, the word bit line WBL is coupled to the high voltage, and the common-source line SL is coupled to the middle voltage or electrically floating. When the field-effect transistor T and the capacitor C are selected to perform an erasing activity, the semiconductor region 104′ is coupled to the high voltage, the word bit line WBL is coupled to the high voltage, and the common-source line SL is coupled to the grounding voltage. When the field-effect transistor T and the capacitor C are not selected to perform an erasing activity, the semiconductor region 104′ is coupled to the high voltage, the word bit line WBL is coupled to the middle voltage or electrically floating, and the common-source line SL is electrically floating. When the field-effect transistor T and the capacitor C are selected to perform a reading activity, the semiconductor region 104′ and the common-source line SL are coupled to the middle voltage and the word bit line WBL is coupled to a low voltage. When the field-effect transistor T and the capacitor C are not selected to perform a reading activity, the semiconductor region 104′ and the word bit line WBL are coupled to the middle voltage and the common-source line SL is coupled to the low voltage or electrically floating. The high voltage is greater than the middle voltage, the middle voltage is greater than the low voltage, and the low voltage is greater than the grounding voltage. When the read-only memory 100′ operates based on channel hot electron injection, the high voltage is slightly lower than the source-to-drain breakdown voltage of the MOSFET T. That is to say, the high voltage is equal to the source-to-drain breakdown voltage of the MOSFET T plus the threshold voltage of the MOSFET T. The middle voltage is equal to the source-to-drain breakdown voltage of the MOSFET T×0.5. The low voltage is equal to the source-to-drain breakdown voltage of the MOSFET T×0.25. The grounding voltage is zero voltage. When the read-only memory 100′ operates based on Fowler-Nordheim tunneling, the high voltage is equal to the breakdown voltage of an interface between the doped well 114′ and the semiconductor region 104′. The middle voltage is equal to the source-to-drain breakdown voltage of the MOSFET T plus the threshold voltage of the MOSFET T. The low voltage is equal to the source-to-drain breakdown voltage of the MOSFET T×0.25. The grounding voltage is zero voltage.

FIG. 13 is a cross-sectional view of a read-only memory according to another embodiment of the present invention. Please refer to FIG. 13. The read-only memory 100′ may be formed in the semiconductor region 104′ implemented with a semiconductor substrate. The other structure of the read-only memory 100′ has been described previously so it will not be reiterated.

According to the embodiments provided above, the read-only memory array and the read-only memory thereof employ the doped well as the path of operating the source to withstand high voltages, thereby improving reliability, life, performance, and anti-interference capabilities.

The embodiments described above are only to exemplify the present invention but not to limit the scope of the present invention. Therefore, any equivalent modification or variation according to the shapes, structures, features, or spirit disclosed by the present invention is to be also included within the scope of the present invention.

What is claimed is:

1. A read-only memory array comprising:
a plurality of common-source lines, arranged in parallel, comprising a first common-source line and a second common-source line;
a plurality of word bit lines arranged in parallel, wherein the plurality of word bit lines perpendicular to the plurality of common-source lines comprise a first word bit line and a second word bit line; and
a plurality of sub-memory arrays each coupled to two of the plurality of common-source lines and two of the plurality of word bit lines, wherein each of the plurality of sub-memory arrays comprises:
a first memory cell with a control terminal thereof coupled to the first word bit line and a data terminal of the first memory cell is coupled to the first common-source line and the first word bit line;
a second memory cell with a control terminal thereof coupled to the second word bit line and a data terminal of the second memory cell is coupled to the first common-source line and the second word bit line;
a third memory cell with a control terminal thereof coupled to the second word bit line and a data terminal of the third memory cell is coupled to the second common-source line and the second word bit line; and
a fourth memory cell with a control terminal thereof coupled to the first word bit line and a data terminal of the fourth memory cell is coupled to the second common-source line and the first word bit line;
wherein the first memory cell, the second memory cell, the third memory cell, and the fourth memory cell, formed in a semiconductor region having a first conductivity type, commonly comprise a first doped well and a second doped well having a second conductivity type opposite to the first conductivity type, the first doped well and the second doped well are formed in the semiconductor region, the first doped well overlaps the first common-source line, the first doped well is coupled to the first common-source line, the second doped well overlaps the second common-source line, and the second doped well is coupled to the second common-source line.

2. The read-only memory array according to claim 1, wherein the first memory cell and the second memory cell are symmetric about the first common-source line, the third memory cell and the fourth memory cell are symmetric about the second common-source line, and the second memory cell and the third memory cell are located between the first memory cell and the fourth memory cell.

3. The read-only memory array according to claim 2, wherein the first memory cell, the second memory cell, the third memory cell, and the fourth memory cell further comprise:
a first gate dielectric block, a second gate dielectric block, a third gate dielectric block, and a fourth gate dielectric block respectively formed on the semiconductor region;
a first conductive gate, a second conductive gate, a third conductive gate, and a fourth conductive gate respectively formed on the first gate dielectric block, the second gate dielectric block, the third gate dielectric block, and the fourth gate dielectric block, the first conductive gate and the second conductive gate overlap the first doped well, the third conductive gate and the fourth conductive gate overlap the second doped well;
a first heavily-doped area formed in the semiconductor region, the first heavily-doped area and the first doped well are respectively formed on two opposite side of the semiconductor region, which is directly arranged under the first conductive gate, and the first heavily-doped area is coupled to the first word bit line, wherein the first heavily-doped area has the second conductivity type;
a second heavily-doped area formed in the semiconductor region, the second heavily-doped area and the second doped well are respectively formed on two opposite side of the semiconductor region, which is directly arranged under the second conductive gate, the second heavily-doped area is coupled to the second word bit line, the second heavily-doped area has the second conductivity type, and the second heavily-doped area and the second doped well are respectively formed on two opposite side of the semiconductor region, which is directly arranged under the third conductive gate; and
a third heavily-doped area formed in the semiconductor region, the third heavily-doped area and the second heavily-doped area are respectively formed on two opposite side of the semiconductor region, which is directly arranged under the fourth conductive gate, the third heavily-doped area is coupled to the first word bit line, the third heavily-doped area has the second conductivity type, and doping concentrations of the first heavily-doped area, the second heavily-doped area, and the third heavily-doped area are greater than those of the first doped well and the second doped well.

4. The read-only memory array according to claim 3, wherein the first conductivity type is a P type and the second conductivity type is an N type.

5. The read-only memory array according to claim 4, wherein when the first memory cell is selected to perform a programming activity, the semiconductor region is coupled to a grounding voltage, the first word bit line is coupled to a middle voltage or a high voltage, and the first common-source line is coupled to the grounding voltage, the middle voltage, or the high voltage; when the first memory cell is not selected to perform a programming activity, the semiconductor region is coupled to the grounding voltage, the first word bit line is coupled to the grounding voltage, and the first common-source line is coupled to a low voltage or electrically floating; when the first memory cell is selected to perform an erasing activity, the semiconductor region is coupled to the grounding voltage, the first word bit line is coupled to the grounding voltage, and the first common-source line is coupled to the high voltage; when the first memory cell is not selected to perform an erasing activity, the semiconductor region is coupled to the grounding voltage, the first word bit line is electrically floating or coupled to the low voltage, and the first common-source line is electrically floating; when the first memory cell is selected to perform a reading activity, the first word bit line is coupled to the low voltage and the semiconductor region and the first common-source line are coupled to the grounding voltage; when the first memory cell is not selected to perform a reading activity, the semiconductor region and the first word bit line are coupled to the grounding voltage and the first common-source line is coupled to the low voltage or electrically floating, wherein the high voltage is greater than the middle voltage, the middle voltage is greater than the low voltage, and the low voltage is greater than the grounding voltage.

6. The read-only memory array according to claim 4, wherein when the second memory cell is selected to perform a programming activity, the semiconductor region is coupled to a grounding voltage, the second word bit line is coupled to a middle voltage or a high voltage, and the first common-source line is coupled to the high voltage, the grounding voltage, or the middle voltage; when the second memory cell is not selected to perform a programming activity, the semiconductor region is coupled to the grounding voltage, the second word bit line is coupled to the grounding voltage, and the first common-source line is coupled to a low voltage or electrically floating; when the second memory cell is selected to perform an erasing activity, the semiconductor region is coupled to the grounding voltage, the second word bit line is coupled to the grounding voltage, and the first common-source line is coupled to the high voltage; when the second memory cell is not selected to perform an erasing activity, the semiconductor region is coupled to the grounding voltage, the second word bit line is electrically floating or coupled to the low voltage, and the first common-source line is electrically floating; when the second memory cell is selected to perform a reading activity, the second word bit line is coupled to the low voltage and the semiconductor region and the first common-source line are coupled to the grounding voltage; when the second memory cell is not selected to perform a reading activity, the semiconductor region and the second word bit line are coupled to the grounding voltage and the first common-source line is coupled to the low voltage or electrically floating, wherein the high voltage is greater than the middle voltage, the middle voltage is greater than the low voltage, and the low voltage is greater than the grounding voltage.

7. The read-only memory array according to claim 4, wherein when the third memory cell is selected to perform a programming activity, the semiconductor region is coupled to a grounding voltage, the second word bit line is coupled to a middle voltage or a high voltage, and the second common-source line is coupled to the high voltage, the grounding voltage, or the middle voltage; when the third memory cell is not selected to perform a programming activity, the semiconductor region is coupled to the grounding voltage, the second word bit line is coupled to the grounding voltage, and the second common-source line is coupled to a low voltage or electrically floating; when the third memory cell is selected to perform an erasing activity, the semiconductor region is coupled to the grounding voltage, the second word bit line is coupled to the grounding voltage, and the second common-source line is coupled to the high voltage; when the third memory cell is not selected to perform an erasing activity, the semiconductor region is coupled to the grounding voltage, the second word bit line is electrically floating or coupled to the low voltage, and the second common-source line is electrically floating; when the third memory cell is selected to perform a reading activity, the second word bit line is coupled to the low voltage and the semiconductor region and the second common-source line are coupled to the grounding voltage; when the third memory cell is not selected to perform a reading activity, the semiconductor region and the second word bit line are coupled to the grounding voltage and the second common-source line is coupled to the low voltage or electrically floating, wherein the high voltage is greater than the middle voltage, the middle voltage is greater than the low voltage, and the low voltage is greater than the grounding voltage.

8. The read-only memory array according to claim 4, wherein when the fourth memory cell is selected to perform a programming activity, the semiconductor region is coupled to a grounding voltage, the first word bit line is coupled to a middle voltage or a high voltage, and the second common-source line is coupled to the high voltage, the grounding voltage, or the middle voltage; when the fourth memory cell is not selected to perform a programming activity, the semiconductor region is coupled to the grounding voltage, the first word bit line is coupled to the grounding voltage, and the second common-source line is coupled to a low voltage or electrically floating; when the fourth memory cell is selected to perform an erasing activity, the semiconductor region is coupled to the grounding voltage, the first word bit line is coupled to the grounding voltage, and the second common-source line is coupled to the high voltage; when the fourth memory cell is not selected to perform an erasing activity, the semiconductor region is coupled to the grounding voltage, the first word bit line is electrically floating or coupled to the low voltage, and the second common-source line is electrically floating; when the fourth memory cell is selected to perform a reading activity, the first word bit line is coupled to the low voltage and the semiconductor region and the second common-source line are coupled to the grounding voltage; when the fourth memory cell is not selected to perform a reading activity, the semiconductor region and the first word bit line are coupled to the grounding voltage and the second common-source line is coupled to the low voltage or electrically floating, wherein the high voltage is greater than the middle voltage, the middle voltage is greater than the low voltage, and the low voltage is greater than the grounding voltage.

9. The read-only memory array according to claim 3, wherein the first conductivity type is an N type and the second conductivity type is a P type.

10. The read-only memory array according to claim 9, wherein when the first memory cell is selected to perform a programming activity, the semiconductor region is coupled to a high voltage, the first word bit line is coupled to a middle voltage or a grounding voltage, and the first common-source line is coupled to the grounding voltage, the middle voltage, or the high voltage; when the first memory cell is not selected to perform a programming activity, the semiconductor region is coupled to the high voltage, the first word bit line is coupled to the high voltage, and the first common-source line is coupled to the middle voltage or electrically floating; when the first memory cell is selected to perform an erasing activity, the semiconductor region is coupled to the high voltage, the first word bit line is coupled to the high voltage, and the first common-source line is coupled to the grounding voltage; when the first memory cell is not selected to perform an erasing activity, the semiconductor region is coupled to the high voltage, the first word bit line is coupled to the middle voltage or electrically floating, and the first common-source line is electrically floating; when the first memory cell is selected to perform a reading activity, the semiconductor region and the first common-source line are coupled to the middle voltage and the first word bit line is coupled to a low voltage; when the first memory cell is not selected to perform a reading activity, the semiconductor region and the first word bit line are coupled to the middle voltage and the first common-source line is coupled to the low voltage or electrically floating, wherein the high voltage is greater than the middle voltage, the middle voltage is greater than the low voltage, and the low voltage is greater than the grounding voltage.

11. The read-only memory array according to claim 9, wherein when the second memory cell is selected to perform a programming activity, the semiconductor region is coupled to a high voltage, the second word bit line is coupled to a middle voltage or a grounding voltage, and the first common-source line is coupled to the grounding voltage, the middle voltage, or the high voltage; when the second memory cell is not selected to perform a programming activity, the semiconductor region is coupled to the high voltage, the second word bit line is coupled to the high voltage, and the first common-source line is coupled to the middle voltage or electrically floating; when the second memory cell is selected to perform an erasing activity, the semiconductor region is coupled to the high voltage, the second word bit line is coupled to the high voltage, and the first common-source line is coupled to the grounding voltage; when the second memory cell is not selected to perform an erasing activity, the semiconductor region is coupled to the high voltage, the second word bit line is coupled to the middle voltage or electrically floating, and the first common-source line is electrically floating; when the second memory cell is selected to perform a reading activity, the semiconductor region and the first common-source line are coupled to the middle voltage and the second word bit line is coupled to a low voltage; when the second memory cell is not selected to perform a reading activity, the semiconductor region and the second word bit line are coupled to the middle voltage and the first common-source line is coupled to the low voltage or electrically floating, wherein the high voltage is greater than the middle voltage, the middle voltage is greater than the low voltage, and the low voltage is greater than the grounding voltage.

12. The read-only memory array according to claim 9, wherein when the third memory cell is selected to perform a programming activity, the semiconductor region is coupled to a high voltage, the second word bit line is coupled to a middle voltage or a grounding voltage, and the second common-source line is coupled to the grounding voltage, the middle voltage, or the high voltage; when the third memory cell is not selected to perform a programming activity, the semiconductor region is coupled to the high voltage, the second word bit line is coupled to the high voltage, and the second common-source line is coupled to the middle voltage or electrically floating; when the third memory cell is selected to perform an erasing activity, the semiconductor region is coupled to the high voltage, the second word bit line is coupled to the high voltage, and the second common-source line is coupled to the grounding voltage; when the third memory cell is not selected to perform an erasing activity, the semiconductor region is coupled to the high voltage, the second word bit line is coupled to the middle voltage or electrically floating, and the second common-source line is electrically floating; when the third memory cell is selected to perform a reading activity, the semiconductor region and the second common-source line are coupled to the middle voltage and the second word bit line is coupled to a low voltage; when the third memory cell is not selected to perform a reading activity, the semiconductor region and the second word bit line are coupled to the middle voltage and the second common-source line is coupled to the low voltage or electrically floating, wherein the high voltage is greater than the middle voltage, the middle voltage is greater than the low voltage, and the low voltage is greater than the grounding voltage.

13. The read-only memory array according to claim 9, wherein when the fourth memory cell is selected to perform a programming activity, the semiconductor region is coupled to a high voltage, the first word bit line is coupled to a middle voltage or a grounding voltage, and the second common-source line is coupled to the grounding voltage, the middle voltage, or the high voltage; when the fourth memory cell is not selected to perform a programming activity, the semiconductor region is coupled to the high voltage, the first word bit line is coupled to the high voltage, and the second common-source line is coupled to the middle voltage or electrically floating; when the fourth memory cell is selected to perform an erasing activity, the semiconductor region is coupled to the high voltage, the first word bit line is coupled to the high voltage, and the second common-source line is coupled to the grounding voltage; when the fourth memory cell is not selected to perform an erasing activity, the semiconductor region is coupled to the high voltage, the first word bit line is coupled to the middle voltage or electrically floating, and the second common-source line is electrically floating; when the fourth memory cell is selected to perform a reading activity, the semiconductor region and the second common-source line are coupled to the middle voltage and the first word bit line is coupled to a low voltage; when the fourth memory cell is not selected to perform a reading activity, the semiconductor region and the first word bit line are coupled to the middle voltage and the second common-source line is coupled to the low voltage or electrically floating, wherein the high voltage is greater than the middle voltage, the middle voltage is greater than the low voltage, and the low voltage is greater than the grounding voltage.

14. The read-only memory array according to claim 3, wherein the semiconductor region is a semiconductor substrate or an epitaxial layer formed on a semiconductor substrate.

15. A read-only memory comprising:
a field-effect transistor with a drain thereof coupled to a word bit line and a source of the field-effect transistor is coupled to a common-source line, wherein the word bit line is perpendicular to the common-source line; and
a capacitor with one terminal thereof coupled to a gate of the field-effect transistor and another terminal of the capacitor is coupled to the word bit line;
wherein the field-effect transistor and the capacitor, formed in a semiconductor region having a first conductivity type, commonly comprise a doped well having a second conductivity type opposite to the first conductivity type, the doped well is formed in the semiconductor region and coupled to the common-source line, and the doped well overlaps the common-source line.

16. The read-only memory according to claim 15, wherein the field-effect transistor and the capacitor further comprise:
a gate dielectric block formed on the semiconductor region;
a conductive gate, formed on the gate dielectric block, overlapping the doped well; and
a heavily-doped area, formed in the semiconductor region, having a doping concentration greater than a doping concentration of the doped well, the heavily-doped area and the doped well are respectively formed on two opposite side of the semiconductor region, which is directly arranged under the conductive gate, the heavily-doped area is coupled to the word bit line, and the heavily-doped area has the second conductivity type.

17. The read-only memory according to claim 15, wherein the first conductivity type is a P type and the second conductivity type is an N type.

18. The read-only memory according to claim 17, wherein when the field-effect transistor and the capacitor are selected to perform a programming activity, the semiconductor region is coupled to a grounding voltage, the word bit line is coupled to a middle voltage or a high voltage, and the common-source line is coupled to the grounding voltage, the middle voltage, or the high voltage; when the field-effect transistor and the capacitor are not selected to perform a programming activity, the semiconductor region is coupled to the grounding voltage, the word bit line is coupled to the grounding voltage, and the common-source line is coupled to a low voltage or electrically floating; when the field-effect transistor and the capacitor are selected to perform an erasing activity, the semiconductor region is coupled to the grounding voltage, the word bit line is coupled to the grounding voltage, and the common-source line is coupled to the high voltage; when the field-effect transistor and the capacitor are not selected to perform an erasing activity, the semiconductor region is coupled to the grounding voltage, the word bit line is electrically floating or coupled to the low voltage, and the common-source line is electrically floating; when the field-effect transistor and the capacitor are selected to perform a reading activity, the word bit line is coupled to the low voltage and the semiconductor region and the common-source line are coupled to the grounding voltage; when the field-effect transistor and the capacitor are not selected to perform a reading activity, the semiconductor region and the word bit line are coupled to the grounding voltage and the common-source line is coupled to the low voltage or electrically floating, wherein the high voltage is greater than the middle voltage, the middle voltage is greater than the low voltage, and the low voltage is greater than the grounding voltage.

19. The read-only memory according to claim 15, wherein the first conductivity type is an N type and the second conductivity type is a P type.

20. The read-only memory according to claim 19, wherein when the field-effect transistor and the capacitor are selected to perform a programming activity, the semiconductor region is coupled to a high voltage, the word bit line is coupled to a middle voltage or a grounding voltage, and the common-source line is coupled to the grounding voltage, the middle voltage, or the high voltage; when the field-effect transistor and the capacitor are not selected to perform a programming activity, the semiconductor region is coupled to the high voltage, the word bit line is coupled to the high voltage, and the common-source line is coupled to the middle voltage or electrically floating; when the field-effect transistor and the capacitor are selected to perform an erasing activity, the semiconductor region is coupled to the high voltage, the word bit line is coupled to the high voltage, and the common-source line is coupled to the grounding voltage; when the field-effect transistor and the capacitor are not selected to perform an erasing activity, the semiconductor region is coupled to the high voltage, the word bit line is coupled to the middle voltage or electrically floating, and the common-source line is electrically floating; when the field-effect transistor and the capacitor are selected to perform a reading activity, the semiconductor region and the common-source line are coupled to the middle voltage and the word bit line is coupled to a low voltage; when the field-effect transistor and the capacitor are not selected to perform a reading activity, the semiconductor region and the word bit line are coupled to the middle voltage and the common-source line is coupled to the low voltage or electrically floating, wherein the high voltage is greater than the middle voltage, the middle voltage is greater than the low voltage, and the low voltage is greater than the grounding voltage.

21. The read-only memory according to claim 15, wherein the semiconductor region is a semiconductor substrate or an epitaxial layer formed on a semiconductor substrate.
